(19) United States
(12) Patent Application Publication
(10) Pub. No.: US 2021/0013329 A1
(43) Pub. Date: Jan. 14, 2021

(54) ARRAY SUBSTRATE AND METHOD FOR MANUFACTURING THE SAME

(71) Applicant: WUHAN CHINA STAR OPTOELECTRONICS SEMICONDUCTOR DISPLAY TECHNOLOGY CO., LTD., Wuhan (CN)

(72) Inventor: Guoqing CHAI, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 16/765,172

(22) PCT Filed: Oct. 21, 2019
(86) PCT No.: PCT/CN2019/112221

§ 371 Date: May 19, 2020

(30) Foreign Application Priority Data
Jul. 9, 2019 (CN) 201910615376.6

(51) Int. Cl. H01L 29/66; H01L 29/786

(52) U.S. Cl. CPC H01L 29/66969; H01L 27/1225; H01L 29/7869

(57) ABSTRACT

An array substrate and a method for manufacturing the same are provided. In the method for manufacturing an array substrate, the conductivization of the active layer is advanced to be performed before the step of lifting off the photoresist. The method further replaces oxygen used in the prior art method with helium to enhance the manufacturing efficiency, reduce the production cost, and improve the production yield.

### FIELD OF INVENTION

The present invention generally relates to the field of display devices and, more particularly, to an array substrate and a method for manufacturing the array substrate.

### BACKGROUND OF INVENTION

The active-matrix organic light-emitting diode (AMOLED) has advantages such as self-luminescence, bright colors, high contrast, fast response, low power consumption, etc., and is expected to replace the thin-film transistor liquid-crystal display (TFT-LCD) and become the mainstream of the next-generation display technology. The AMOLED has higher requirements for thin-film transistors (TFTs), and two conventional TFTs, namely, the amorphous silicon (a-Si) TFT and the low-temperature poly-silicon (LTPS) TFT, are not suitable for large-area AMOLED displays. Although the LTPS TFT has higher mobility and thus better electrical stability, it has poor uniformity of electrical characteristics over a large area. On the other hand, although the a-Si TFT has better uniformity over a large area, its mobility is too low, and there is a serious characteristic drift. The foregoing shortcomings limit the applications of silicon- (Si-) based TFTs in large-area AMOLED pixel circuits.

The indium-gallium-zinc oxide (IGZO) TFT is a new TFT technology developed in recent years. It has advantages such as high mobility, good uniformity, and low production cost, which may facilitate the mass production of AMOLEDs. More particularly, good large-area uniformity makes the IGZO TFT a competitive display device.

In the current manufacturing process of a top-gate IGZO TFT device, the substrate is required to enter the drying chamber to complete the etching of the insulating layer between the gate layer and the active layer and the conductivization of the active layer. In addition, the gas used in the etching of the insulating layer contains carbon tetrafluoride and oxygen, and the reaction in which oxygen is involved may result in contaminants, thereby causing defects on the circuit displayed as small black spots under an optical microscope. On the other hand, the presence of oxygen also leads to denaturation of the photoresist, resulting in the presence of residual photoresist on the electrode wire after subsequent manufacturing steps. Therefore, the use of the conventional manufacturing process has a negative impact on productivity.

### SUMMARY OF INVENTION

One object of the present invention is to provide an array substrate and a method for manufacturing the array substrate to solve cumbersome manufacturing processes in the prior art and overcome the defect that oxygen in the gaseous etchant appears as small black spots on the circuit under optical microscopy as well as the problem that oxygen causes the photoresist to denature and remain on the electrode wires after subsequent manufacturing processes.

To achieve the foregoing object, the present invention provides a method for manufacturing an array substrate, which includes the steps of:

providing a substrate;

depositing an active layer, a gate insulating layer, and a gate layer sequentially on the substrate;

coating a photoresist on the gate layer and wet-etching the gate layer;

dry-etching the gate insulating layer;

conductivizing the active layer; and

lifting off the photoresist.

Furthermore, the step of dry-etching the gate insulating layer includes the step of: injecting a gaseous etchant into a reaction chamber to form the gate insulating layer by dry-etching, wherein the gaseous etchant includes carbon tetrafluoride and helium.

Furthermore, in the step of injecting a gaseous etchant into a reaction chamber, carbon tetrafluoride and helium are simultaneously injected, wherein the flow ratio of carbon tetrafluoride to helium is from 2:1 to 6:1.

Furthermore, the step of conductivizing the active layer includes the step of: in the reaction chamber, stopping injecting carbon tetrafluoride and increasing the flow of helium, increasing the power of plasma bombardment, and conductivizing the active layer, wherein the flow rate of helium is increased by 1 to 15 times.

Furthermore, the step of lifting off the photoresist includes the steps of: in the reaction chamber, injecting oxygen and ashing the photoresist to remove part of the photoresist, and removing the remaining photoresist by wet lift-off.

Furthermore, the step of providing a substrate includes the steps of: providing a bottom layer, forming a light shielding layer on the bottom layer, and forming a buffer layer on the bottom layer and the light shielding layer.

Furthermore, the step of coating a photoresist on the gate layer and wet-etching the gate layer includes the steps of: coating the photoresist on a surface of the gate layer away from the gate insulating layer, and wet-etching the photoresist to the gate layer to pattern the gate layer after the photoresist is exposed and developed.

The present invention further provides an array substrate manufactured by the method for manufacturing an array substrate as disclosed above.

Furthermore, the array substrate includes a substrate, an active layer, a gate insulating layer, and a gate layer. The active layer is disposed on the substrate. The gate insulating layer is disposed on the active layer. The gate layer is disposed on a surface of the gate insulating layer away from the active layer and corresponds to the active layer.

Furthermore, the substrate includes a bottom layer, a light shielding layer, and a buffer layer. The light shielding layer is disposed on a surface of the bottom layer adjacent to the active layer and corresponds to the active layer. The buffer layer covers the bottom layer and the light shielding layer such that the active layer is disposed on a surface of the buffer layer away from the light shielding layer.

The present invention has the advantages that the present invention provides an array substrate and a method for manufacturing the same. In the method, the conductivization of the active layer is advanced to be performed before the step of lifting off the photoresist. On the contrary, in the prior art method, the conductivization of the active layer is performed after the step of lifting off the photoresist. Therefore, the method according to the present invention can reduce the step of entering the gas reaction chamber once, and the method according to the present invention replaces oxygen used in the prior art method with helium to solve the problem due to residual photoresist, prevent oxygen from generating defects on the circuit, and improve the production yield. The method according to the present invention can further improve the slope angle of the gate layer, shorten the channel length of the array substrate, and thereby reduce the short channel effect.

### DESCRIPTION OF DRAWINGS

In order to more clearly illustrate the technical solutions in the embodiments of the present invention, the drawings used in the description of the embodiments will be briefly described below. Obviously, the drawings in the following description are only some embodiments of the present invention. Other drawings may be obtained, without creative efforts, by those of ordinary skill in the art in light of these drawings.

FIG. 1 is a schematic flowchart of a method for manufacturing an array substrate according to one embodiment of the present invention;

FIG. 2 is a specific flowchart of Step S10 according to one embodiment of the present invention;

FIG. 3 is a cross-sectional schematic view of an array substrate after Step S10 according to one embodiment of the present invention;

FIG. 4 is a cross-sectional schematic view of an array substrate after Step S20 according to one embodiment of the present invention;

FIG. 5 is a cross-sectional schematic view of an array substrate after Step S30 according to one embodiment of the present invention;

FIG. 6 is a cross-sectional schematic view of an array substrate after Step S40 according to one embodiment of the present invention;

FIG. 7 is a cross-sectional schematic view of an array substrate after Step S50 according to one embodiment of the present invention; and

FIG. 8 is a cross-sectional schematic view of an array substrate according to one embodiment of the present invention.

The elements with reference numerals in the drawings:

| | |
|---|---|
| array substrate 100 | |
| substrate 110 | bottom layer 111 |
| light shielding layer 112 | buffer layer 113 |
| active layer 120 | gate insulating layer 130 |
| gate layer 140 | photoresist 150 |

### DETAILED DESCRIPTION OF PREFERRED EMBODIMENTS

The preferred embodiments of the present invention will be described with reference to the accompanying drawings, which are to be construed as illustrative implementations of the present invention. The embodiments of the present invention can be fully introduced to those skilled in the art to make the technical contents clearer and easier to be understood. The present invention can be implemented in many different forms of inventive embodiments, and the scope of the present invention is not limited to the embodiments described herein.

In the drawings, structurally identical elements are denoted by identical reference numerals, and structurally or functionally similar elements are denoted by similar reference numerals. The dimension and thickness of each element shown in the drawings are arbitrarily shown, and the dimension and thickness of each element are not limited in the present invention. In order to make the drawings clearer, some parts of the drawings appropriately exaggerate the thickness of the elements.

In addition, the following descriptions of the various embodiments of the present invention with reference to the accompanying drawings exemplify particular embodiments of the present invention. The directional terms mentioned in the present invention, such as “upper”, “lower”, “front”, “rear”, “left”, “right”, “inner”, “outer”, “side”, etc., only illustrate the directions in the accompanying drawings. Therefore, the directional terms are used to describe and understand the present invention in a better and clearer manner, instead of limiting the present invention by indicating or implying that the device or the element referred to must have a particular orientation or be constructed or operate in a particular orientation. Moreover, the terms “first”, “second”, “third”, and the like are used for descriptive purposes only and are not to be construed as indicating or implying relative importance.

When an element is described as being “on” another element, the element can be placed directly on the other element. An intermediate element, on which the element is placed, can also be provided on another element. When an element is described as being “mounted to” or “connected to” another element, it can be understood that the element is being directly “mounted” or “connected”, or the element is “mounted” or “connected” to another element through an intermediate element.

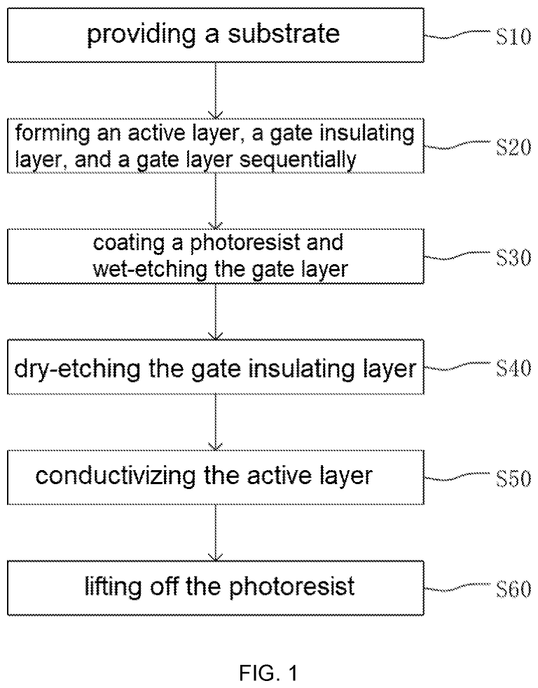

A method for fabricating an array substrate 100 is provided in one embodiment of the present invention. A flowchart of the method is as shown in FIG. 1. The method for fabricating an array substrate 100 includes the following steps:

In Step S10, a substrate 110 is provided.

As shown in FIG. 3, the substrate 110 includes a bottom layer 111, a light shielding layer 112, and a buffer layer 113. The light shielding layer 112 is disposed on the bottom layer 111, and the buffer layer 113 covers the light shielding layer 112 and the bottom layer 111.

In Step S20, an active layer 120, a gate insulating layer 130, and a gate layer 140 are sequentially formed on the substrate 110.

The cross-sectional schematic view of the array substrate 100 after Step S20 is as shown in FIG. 4.

A metal oxide layer is deposited on the substrate 110, and the metal oxide layer includes indium-gallium-zinc oxide (IGZO). The metal oxide is then patterned to form the active layer 120, and the active layer 120 corresponds to the light shielding layer 112.

A gate insulating layer 130 is formed on the substrate 110, and the gate insulating layer 130 covers the active layer 120. The gate insulating layer 130 is an insulating material, which may include silicon oxide, silicon nitride, silicon oxynitride or any combination thereof.

A gate layer 140 is formed on the gate insulating layer 130. The gate layer 140 is a metal with excellent electric conductivity, and may be an alloy including molybdenum, aluminum, copper, silver, or any combination thereof.

In Step S30, a photoresist 150 is coated on the gate layer 140 and wet-etching is performed on the gate layer 140.

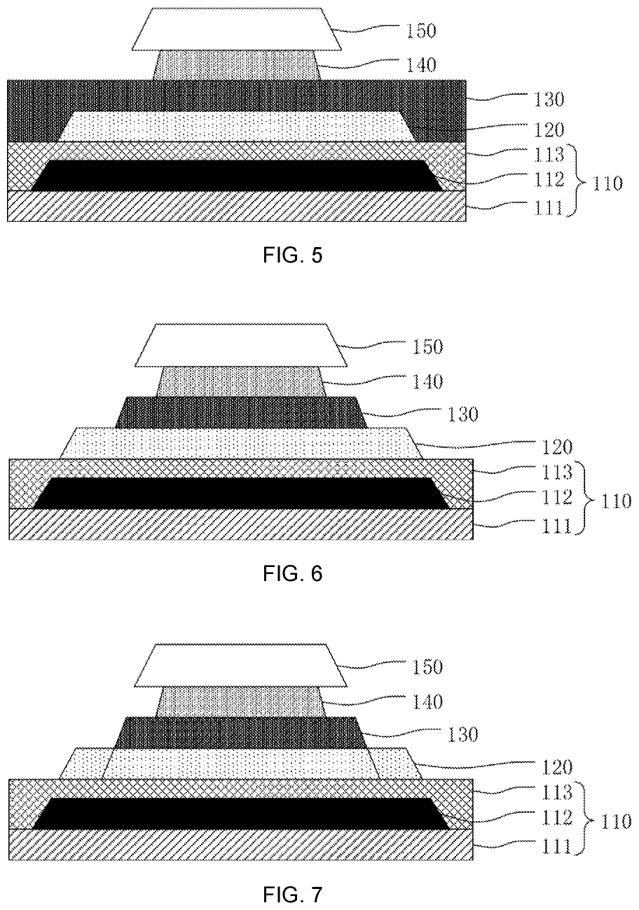

The cross-sectional schematic view of the array substrate 100 after Step S30 is as shown in FIG. 5.

A photoresist 150 is coated on the gate layer 140, and the photoresist 150 is then cured and patterned by exposure and development. The cured and patterned photoresist 150 is then etched by an etchant to the gate layer 140 to pattern the gate layer 140.

In Step S40, dry-etching is performed on the gate insulating layer 130.

The cross-sectional schematic view of the array substrate 100 after Step S40 is as shown in FIG. 6.

The substrate 110 is moved into a closed reaction chamber, and an gaseous etchant including carbon tetrafluoride and helium is simultaneously injected into the reaction chamber to conduct dry-etching and pattern the gate insulating layer 130. The flow rate of carbon tetrafluoride is 2000 to 6000 sccm, the flow rate of helium is 1000 sccm, and the flow ratio of carbon tetrafluoride to helium is from 2:1 to 6:1.

In Step S50, the active layer 120 is conductivized.

The cross-sectional schematic view of the array substrate 100 after Step S50 is as shown in FIG. 7.

In the reaction chamber, the injection of carbon tetrafluoride is stopped to increase the flow rate of helium from 1000 sccm to 3000 sccm to enhance the power of plasma bombardment and conductivize the active layer 120 so that the active layer 120 becomes a semiconductor. In one embodiment of the present invention, the flow rate of helium is increased by 3 times, but in other embodiments of the present invention, the flow rate of helium is increased by 1 to 15 times. The other steps in these embodiments are the same as the steps in the foregoing embodiment of the present invention, and therefore the details thereof are not repeated herein.

In Step S60, the photoresist 150 is lifted off.

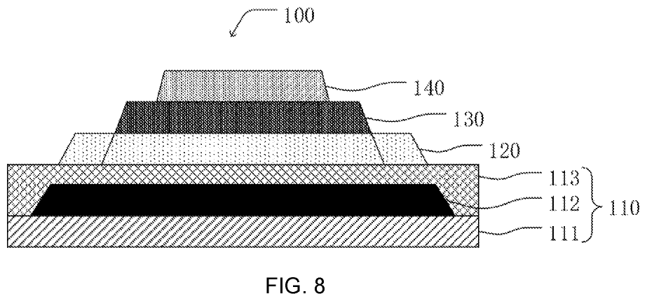

The cross-sectional schematic view of the array substrate 100 after Step S60 is as shown in FIG. 8.

After the conductivization of the active layer 120 is completed, the injection of helium is stopped and followed by the injection of oxygen into the reaction chamber to ash the photoresist 150 and remove part of the photoresist 150. The substrate 110 is then removed from the reaction chamber, and the remaining photoresist 150 is removed by wet lift-off.

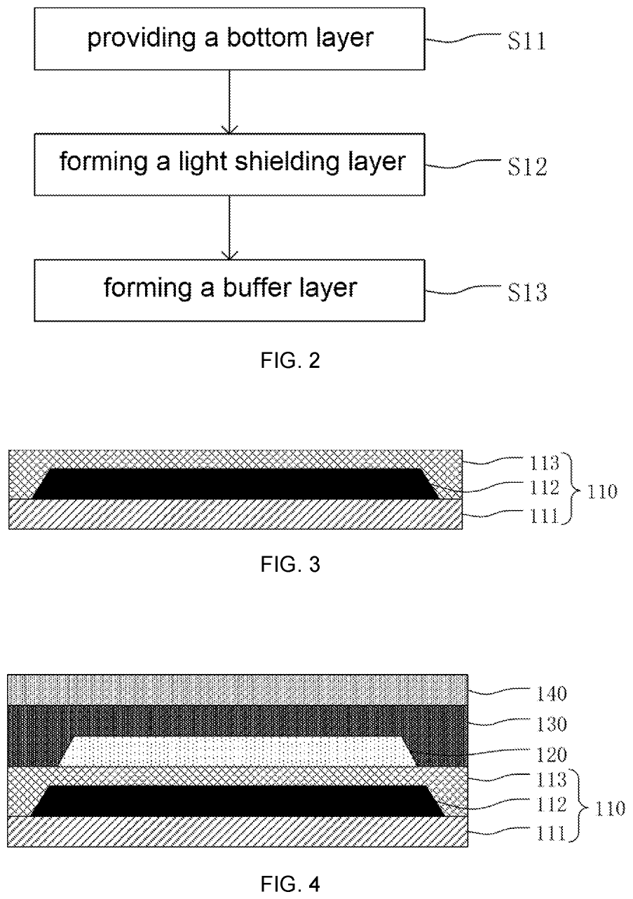

Specifically, the step of providing a substrate 110 further includes Steps S11 to S13, and a specific flowchart thereof is as shown in FIG. 2, including the steps as follows:

In Step S11, a bottom layer 111 is provided.

The bottom layer 111 may be a glass bottom layer, a quartz bottom layer, or a flexible bottom layer. In one embodiment of the present invention, the bottom layer 111 is a glass bottom layer.

In Step S12, a light shielding layer 112 is formed on the bottom layer 111.

An opaque material is deposited on the bottom layer 111 to form a light-shielding layer 112. A pattern is formed on the light-shielding layer 112 using a mask and is then etched to pattern the light-shielding layer 112.

In Step S13, a buffer layer 113 is formed on the bottom layer 111 and the light shielding layer 112.

The buffer layer 113 is deposited on the bottom layer 111 and the light shielding layer 112 by a chemical deposition method or the like.

In the method for manufacturing the array substrate 100 according to one embodiment of the present invention, the conductivization of the active layer 120 is advanced to be performed before the step of lifting off the photoresist 150. On the contrary, in the prior art method, the conductivization of the active layer 120 is performed after the step of lifting off the photoresist 150. Therefore, the method according to the present invention can reduce the step of entering the gas reaction chamber once, and the method according to the present invention replaces oxygen used in the prior art method with helium to solve the problem due to residual photoresist 150, prevent oxygen from generating defects on the circuit, and improve the production yield. The method according to the present invention can further improve the slope angle of the gate layer 140, shorten the channel length of the array substrate 100, and thereby reduce the short channel effect.

An array substrate 100 is also provided in one embodiment of the present invention. The array substrate 100 is manufactured by the method for manufacturing an array substrate 100 according to one embodiment of the present invention. As shown in FIG. 8, the array substrate 100 includes a substrate 110, an active layer 120, a gate insulating layer 130, and a gate layer 140.

The substrate 110 includes a bottom layer 111, a light shielding layer 112, and a buffer layer 113.

The bottom layer 111 may be a glass bottom layer, a quartz bottom layer, or a flexible bottom layer. In one embodiment of the present invention, the bottom layer 111 is a glass bottom layer.

The light shielding layer 112 is disposed on the bottom layer 111 and is formed by depositing an opaque material. Since the active layer 120 is very sensitive to light, the light may affect the operation of the active layer 120. Therefore, the light shielding layer 112 is disposed to shield the active layer 120 from light.

The buffer layer 113 covers the light shielding layer 112 and the bottom layer 111. The buffer layer 113 is used to insulate the light shielding layer 112 from the active layer 120 and protect the whole structure of the array substrate 100 from oxygen to reduce the corrosion of oxygen on the devices in the array substrate 100.

The active layer 120 is disposed on a surface of the buffer layer 113 away from the light shielding layer 112 and corresponds to the light shielding layer 112. The active layer 120 is a metal oxide including indium-gallium-zinc oxide (IGZO).

The gate insulating layer 130 is disposed on a surface of the active layer 120 away from the buffer layer 113 for insulating the active layer 120 and the gate layer 140 to prevent a short circuit. The gate insulating layer 130 may be an insulating material including silicon oxide, silicon nitride, or silicon oxynitride.

The gate layer 140 is disposed on a surface of the gate insulating layer 130 away from the active layer 120. When a voltage is applied to the gate layer 140, an electric field is generated by a gate voltage in the gate insulating layer 130. Electric lines of force are directed from the gate electrode to the surface of the active layer 120, and generate induced charges on the surface. The gate layer 140 is a metal with excellent electric conductivity, and may be an alloy including molybdenum, aluminum, copper, silver, or any combination thereof.

The array substrate 100 provided by the present invention is manufactured by the above-mentioned method for manufacturing the array substrate 100, which uses simple manufacturing processes to improves production efficiency, reduces production cost, and increase production yield.

Although the present invention has been described herein with reference to specific embodiments, it is understood that these embodiments are merely illustrative of the principles and applications of the present invention. It is understood that many modifications may be made to the exemplary embodiments, and other arrangements may be made without departing from the spirit and the scope of the present invention as defined by the appended claims. It is understood that the different dependent claims and the features described in the specification may be combined in a manner different from that described in the original claims. It is also understood that the features described in connection with the individual embodiments can be used in other described embodiments.

What is claimed is:

1. A method for manufacturing an array substrate, comprising:
providing a substrate;
depositing an active layer, a gate insulating layer, and a gate layer sequentially on the substrate;
coating a photoresist on the gate layer and wet-etching the gate layer;
dry-etching the gate insulating layer;
conductivizing the active layer; and
lifting off the photoresist.

2. The method for manufacturing an array substrate according to claim 1, wherein,
the step of dry-etching the gate insulating layer comprises:
injecting a gaseous etchant into a reaction chamber to form the gate insulating layer by dry-etching,
wherein the gaseous etchant comprises carbon tetrafluoride and helium.

3. The method for manufacturing an array substrate according to claim 2, wherein,
in the step of injecting a gaseous etchant into a reaction chamber, carbon tetrafluoride and helium are simultaneously injected,
wherein the flow ratio of carbon tetrafluoride to helium is from 2:1 to 6:1.

4. The method for manufacturing an array substrate according to claim 2, wherein,
the step of conductivizing the active layer comprises:
in the reaction chamber, stopping injecting carbon tetrafluoride and increasing the flow of helium, increasing the power of plasma bombardment, and conductivizing the active layer,
wherein the flow rate of helium is increased by 1 to 15 times.

5. The method for manufacturing an array substrate according to claim 1, wherein,
the step of lifting off the photoresist comprises:
in the reaction chamber, injecting oxygen and ashing the photoresist to remove part of the photoresist; and
removing the remaining photoresist by wet lift-off.

6. The method for manufacturing an array substrate according to claim 1, wherein,
the step of providing a substrate comprises:
providing a bottom layer;
forming a light shielding layer on the bottom layer; and
forming a buffer layer on the bottom layer and the light shielding layer.

7. The method for manufacturing an array substrate according to claim 1, wherein,
the step of coating a photoresist on the gate layer and wet-etching the gate layer comprises:
coating the photoresist on a surface of the gate layer away from the gate insulating layer; and
wet-etching the photoresist to the gate layer to pattern the gate layer after the photoresist is exposed and developed.

8. An array substrate manufactured by the method for manufacturing an array substrate according to claim 1.

9. The array substrate according to claim 8, wherein the array substrate comprises:
a substrate;
an active layer disposed on the substrate;
a gate insulating layer disposed on the active layer; and
a gate layer disposed on a surface of the gate insulating layer away from the active layer and corresponding to the active layer.

10. The array substrate according to claim 9, wherein the substrate comprises:
a bottom layer;
a light shielding layer disposed on a surface of the bottom layer adjacent to the active layer and corresponding to the active layer; and
a buffer layer covering the bottom layer and the light shielding layer such that the active layer is disposed on a surface of the buffer layer away from the light shielding layer.
